(19) United States
(12) Patent Application Publication
(10) Pub. No.: US 2010/0163938 A1
(43) Pub. Date: Jul. 1, 2010

(54) METHOD FOR FORMING SILICIDE IN SEMICONDUCTOR DEVICE

(76) Inventor: Dong-Ho Park, Gangnam-gu (KR)

Correspondence Address: SHERR & VAUGHN, PLLC, 620 HERNDON PARKWAY, SUITE 320, HERNDON, VA, 20170, US

(21) Appl. No.: 12/648,210

(22) Filed: Dec. 28, 2009

(30) Foreign Application Priority Data
Dec. 30, 2008 (KR) 10-2008-0137607

(51) Int. Cl. H01L 29/45; H01L 21/762; H01L 21/3205; H01L 29/78

(52) U.S. Cl. 257/288; 438/296; 257/E21.546; 257/E21.296; 257/E29.255; 257/E29.143

(57) ABSTRACT

A method of forming a silicide in a semiconductor device includes: forming a poly gate on and/or over the upper portion of a silicon substrate having an active area and an STI formed therein; forming a spacer wall on and/or over both sidewalls of the poly gate; forming source/drain by performing high-concentration ion implantation; forming a silicide blocking pattern on and/or over both sidewalls of the spacer wall and on the STI; forming a multilayer silicide material on and/or over substantially the entire surface of the silicon substrate having the silicide blocking pattern formed thereover; and performing an RTA process on the multilayer silicide material to form a silicide by reaction between the poly gate and the source/drain electrode.

The present application claims priority under 35 U.S.C. 119 to Korean Patent Application No. 10-2008-0137607 (filed on Dec. 30, 2008), which is hereby incorporated by reference in its entirety.

### BACKGROUND

With an increase in the integration of a semiconductor device, a width of a line may decrease and a sheet resistance of the line may increase. When the sheet resistance of the line increases, the signal transmission time in the integrated circuit is delayed. In order to prevent the delay of the signal transmission time, a high melting point silicide material having low resistivity and stable characteristics at a high temperature can be applied to the upper portions of the source/drain as well as to the poly gate of the transistor, thereby reducing sheet resistance and contact resistance. In other words, a silicide material having low resistivity can be formed over the upper portions of the poly gate and the source/drain so as to reduce electrical resistance of a gate line formed by the poly gate in the semiconductor device or to reduce contact resistance between the source/drain formed on a single-crystal silicon substrate and a metal line.

Examples of such a silicide material include rare earth metals (for example, tungsten silicide (WSi2), titanium silicide (TiSi2), cobalt silicide (CoSi2), and the like) which react to silicon. As described above, as the silicide material, rare earth metals are used, and among the rare earth metals, titanium silicide and cobalt silicide are generally used. However, when silicide is made of only one material, resistance in the N/P-MOS active area and contact resistance of the poly gate significantly changes, which may cause junction leakage and change in the channel line width.

### SUMMARY

Embodiments relate to a method of forming a silicide in a semiconductor device, which is capable of minimizing junction leakage and change in a channel line width by forming titanium (Ti)/cobalt (Co) in a multilayer on and/or over an upper portions of a poly gate and a source/drain, and forming a silicide by performing a rapid thermal annealing (RTA) process at a predetermined temperature.

In accordance with embodiments, there is provided a method of forming a silicide in a semiconductor device that includes forming a poly gate on and/or over an upper portion of a silicon substrate having an active area and an shallow trench isolation (STI) formed therein; forming a spacer wall on and/or over both sidewalls of the poly gate; forming a source/drain by performing high-concentration ion implantation; forming a silicide blocking pattern on and/or over both sidewalls of the spacer wall and on the STI; forming a multilayer silicide material on and/or over substantially an entire surface of the silicon substrate having the silicide blocking pattern formed thereover; and performing an RTA process on the multilayer silicide material to form a silicide by reaction between the poly gate and the source/drain electrode.

In accordance with embodiments, there is provided a semiconductor device that includes a poly gate formed on and/or over the upper portion of a silicon substrate having an active area and an STI formed therein; a spacer wall formed on and/or over both sidewalls of the poly gate; a source/drain formed by performing high-concentration ion implantation; a silicide blocking pattern formed on and/or over both sidewalls of the spacer wall and on and/or over the STI; a multilayer silicide material formed on and/or over substantially the entire surface of the silicon substrate having the silicide blocking pattern formed thereover; and a silicide formed by performing an RTA process on the multilayer silicide material.

### DRAWINGS

FIGS. 1A to 1E are sectional views illustrating a process of forming a silicide in a semiconductor device according to embodiments.

FIG. 2 is a diagram showing a multilayer silicide material according to embodiments.

FIG. 3 is a diagram showing the detailed profile of an RTA process for forming multilayer silicide according to embodiments.

### DESCRIPTION

In the following description, detailed description of related structures and functions incorporated herein may be omitted when it may make the subject matter of the embodiments unclear.

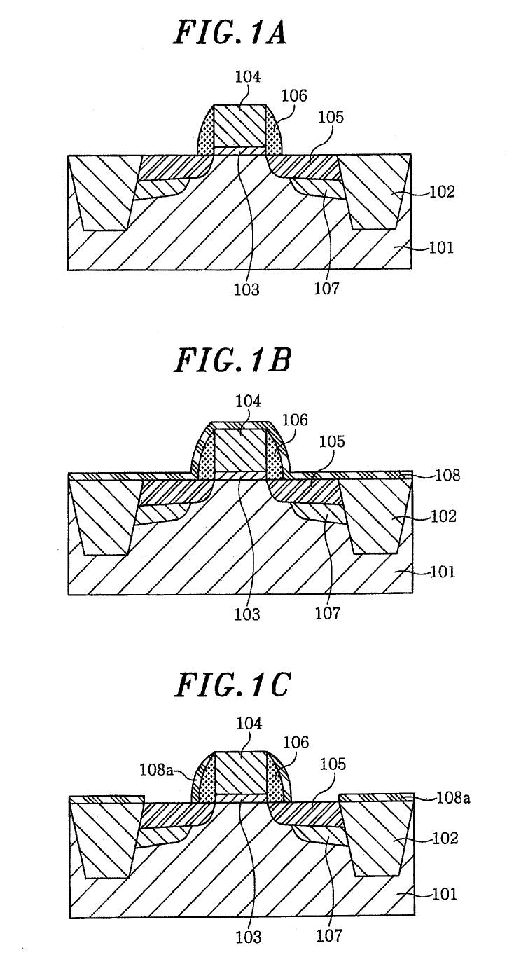

FIGS. 1A to 1E are sectional views illustrating a process of forming a silicide in a semiconductor device according to embodiments. Referring to FIG. 1A, in order to form an active area and a trench area for isolation on and/or over a silicon substrate 101 as a semiconductor substrate, etching may be performed on the silicon substrate 101 with a photoresist (PR) pattern as a mask to form a trench area. The trench area may be buried by an insulating material, and planarization can be performed to polish the insulating material until the silicon substrate 101 is exposed. Thus, the active area and an STI 102 may be formed.

Also referring to FIG. 1A, an insulating film and a gate conductive film may be sequentially deposited over the upper portion of the silicon substrate 101 having the active area and the STI 102 formed therein and then patterned to form a poly gate 104 with a gate insulating film 103. Thereafter, low-concentration ion implantation (for example, ion implantation of N-type dopant with a low concentration) may be performed using the poly gate 104 as an ion implantation mask to form an LDD (Lightly Doped Drain) area 105. Next, an insulating material, for example, a silicon nitride film (SiN) or a silicon oxynitride film (SiON) may be deposited over substantially the entire surface of the silicon substrate 101 and then etched by dry etching to form spacer wall 106 on and/or over both sidewalls of the poly gate 104. Next, high-concentration ion implantation may be performed using the spacer wall 106 and the poly gate 104 as ion implantation masks to form source/drain 107.

As shown in FIG. 1B, a silicide blocking material 108, for example, a TEOS film may be thinly formed on and/or over substantially the entire surface of the silicon substrate 101 having the poly gate 104 and the spacer wall 106 formed thereover. Etching (e.g., dry etching) may be performed on the silicide blocking material 108 using a PR pattern as a mask to form a silicide blocking pattern 108a on and/or over both sidewalls of the spacer wall 106 and on and/or over the upper portion of the STI 102, as shown in FIG. 1C.

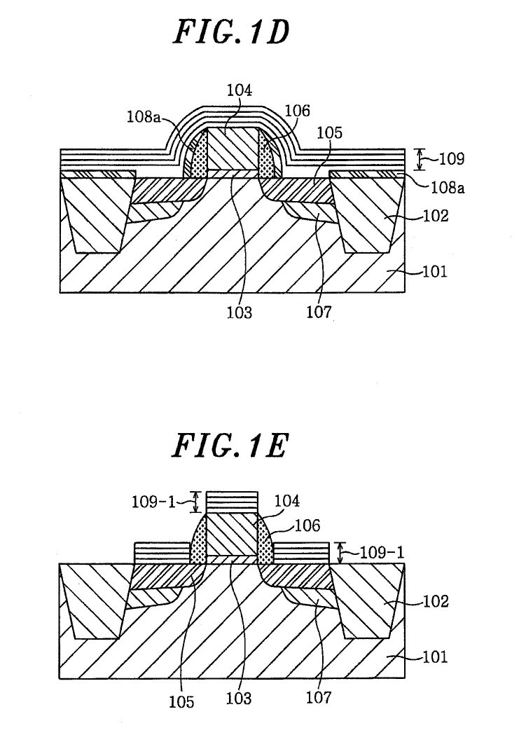

Next, as shown in FIG. 1D, a multilayer silicide material 109 may be formed on and/or over substantially the entire surface of the silicon substrate 101 having the silicide blocking material 108a formed thereover. In this case, the multilayer silicide material may be formed, as shown in FIG. 2, by sequentially forming a titanium (Ti) film 109a, a cobalt (Co) film 109b, a titanium (Ti) film 109c, and a cobalt (Co) film 109d. It is beneficial that the titanium films 109a and 109c are formed to have a thickness of about 60 Å to about 80 Å, and the cobalt films 109b and 109d are formed to have a thickness of about 40 Å to about 60 Å.

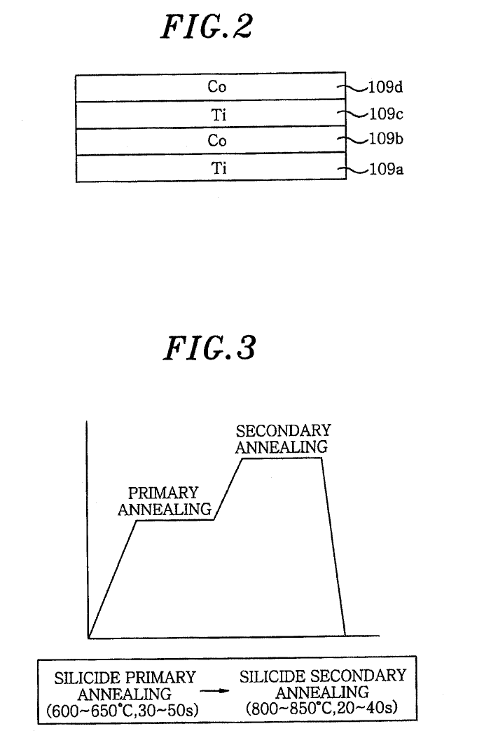

Referring to FIG. 1E, an RTA (rapid thermal annealing) process may be performed at a predetermined temperature on the multilayer silicide material 109 to form a multilayer titanium/cobalt silicide 109-1 through reaction between the poly gate 104 and the source/drain 107. The RTA process, as shown in FIG. 3, can include performing an annealing process two times in consideration of phase changes of titanium and cobalt so as to obtain appropriate resistance. Primary annealing may be performed at a temperature of about 600° to about 650° C. for 30 to 50 seconds, such that titanium forms titanium silicide (TiSi) having a C49 phase, and cobalt forms cobalt silicide (CoSi) having a 1:1 phase. Secondary annealing may be performed at a temperature of about 800° C. to about 850° C. for 20 to 40 seconds, such that titanium forms titanium silicide (TiSi2) having a C54 phase, and cobalt forms cobalt silicide (CoSi2) having a 1:2 phase. Thus, a multilayer silicide may be formed.

As described above, according to embodiments, titanium/cobalt may be formed in multilayer on and/or over the upper portions of the poly gate and the source/drain, and the RTA process may be performed at a predetermined temperature to form a silicide. Therefore, junction leakage and change in a channel line width can be minimized, and resistivity characteristics of the poly gate and the source/drain can be maximized. As a result, semiconductor yield can be maximized as well. Further, the silicide may be formed by integrating formation of titanium/cobalt in multilayer and the RTA process at a predetermined temperature, thereby minimizing a process time.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a poly gate over an upper portion of a silicon substrate having an active area and a shallow trench isolation formed therein;
forming a spacer wall over both sidewalls of the poly gate;
forming source/drain by performing high-concentration ion implantation;
forming a silicide blocking pattern over both sidewalls of the spacer wall and on the shallow trench isolation;
forming a multilayer silicide material over the silicon substrate having the silicide blocking pattern formed thereover; and
performing an rapid thermal annealing process on the multilayer silicide material to form a silicide by reaction between the poly gate and the source/drain electrode.

2. The method of claim 1, wherein the high-concentration ion implantation is performed using the spacer wall and the poly gate as ion implantation masks.

3. The method of claim 1, wherein the silicide blocking pattern is formed by forming a silicide blocking material over substantially the entire surface of the silicon substrate having the poly gate and the spacer walls formed thereover and performing etching with a photoresist pattern as a mask.

4. The method of claim 1, wherein the multilayer silicide material is formed by sequentially forming a titanium (Ti) film, a cobalt (Co) film, a titanium (Ti) film, and a cobalt (Co) film.

5. The method of claim 4, wherein a thickness of the titanium films is in a range of about 60 Å to about 80 Å.

6. The method of claim 4, wherein a thickness of the cobalt films is in a range of about 40 Å to about 60 Å.

7. The method of claim 1, wherein the rapid thermal annealing process includes performing primary annealing and secondary annealing in consideration of phase changes of titanium and cobalt.

8. The method of claim 7, wherein the primary annealing is performed at a temperature of about 600° C. to about 650° C. for about 30 to about 50 seconds.

9. The method of claim 7, wherein the secondary annealing is performed at a temperature of about 800° C. to about 850° C. for about 20 to about 40 seconds.

10. The method of claim 1, wherein the multilayer silicide material is formed over substantially the entire surface of the silicon substrate.

11. An apparatus, comprising:
a poly gate formed over an upper portion of a silicon substrate having an active area and a shallow trench isolation formed therein;
a spacer wall formed over both sidewalls of the poly gate;
a source/drain formed by performing high-concentration ion implantation;
a silicide blocking pattern formed over both sidewalls of the spacer wall and on the shallow trench isolation;
a multilayer silicide material formed over the silicon substrate having the silicide blocking pattern formed thereover; and
a silicide formed by performing a rapid thermal annealing process on the multilayer silicide material.

12. The apparatus of claim 11, wherein the high-concentration ion implantation is performed using the spacer wall and the poly gate as ion implantation masks.

13. The apparatus of claim 11, wherein the silicide blocking pattern is formed by forming a silicide blocking material over the entire surface of the silicon substrate having the poly gate and the spacer wall formed thereover and performing etching with a photoresist pattern as a mask.

14. The apparatus of claim 11, wherein the multilayer silicide material is formed by sequentially forming a titanium (Ti) film, a cobalt (Co) film, a titanium (Ti) film, and a cobalt (Co) film.

15. The apparatus of claim 14, wherein a thickness of the titanium films is in a range of about 60 Å to about 80Å.

16. The apparatus of claim 14, wherein a thickness of the cobalt films is in a range of about 40 Å to about 60 Å.

17. The apparatus of claim 11, wherein the rapid thermal annealing process includes performing primary annealing and secondary annealing in consideration of phase changes of titanium and cobalt.

18. The apparatus of claim 17, wherein the primary annealing is performed at a temperature of about 600° C. to about 650° C. for about 30 to about 50 seconds.

19. The apparatus of claim 17, wherein the secondary annealing is performed at a temperature of about 800° C. to about 850° C. for about 20 to about 40 seconds.

20. The apparatus of claim 11, wherein the multilayer silicide material is formed over substantially the entire surface of the silicon substrate.
